(19) United States
(12) Patent Application Publication
(10) Pub. No.: US 2011/0129991 A1
(43) Pub. Date: Jun. 2, 2011

(54) Methods Of Patterning Materials, And Methods Of Forming Memory Cells

(76) Inventors: Kyle Armstrong, Meridian, ID (US); David A. Kewley, Boise, ID (US); Duane Goodner, Boise, ID (US); Mark Kiehlbauch, Boise, ID (US); Zengtao Liu, Boise, ID (US)

(21) Appl. No.: 12/629,722

(22) Filed: Dec. 2, 2009

(51) Int. Cl. H01L 21/28; G03F 7/20

(52) U.S. Cl. 438/585; 430/323; 430/316; 257/E21.19

(57) ABSTRACT

Some embodiments include methods of patterning materials. A mass may be formed over a material, and a first mask may be formed over the mass. First spacers may be formed along features of the first mask, and then the first mask may be removed to leave a second mask corresponding to the first spacers. A pattern of the second mask may be partially transferred into the mass to form an upper portion of the mass into a third mask. The first spacers may be removed from over the third mask, and then second spacers be formed along features of the third mask. The second spacers are a fourth mask. A pattern of the fourth mask may be transferred into a bottom portion of the mass, and then the bottom portion may be used as a mask during processing of the underlying material.

### TECHNICAL FIELD

Methods of patterning materials, and methods of forming memory cells.

### BACKGROUND

Integrated circuits may be formed on a semiconductor substrate, such as a silicon wafer or other semiconducting material. In general, layers of various materials which are either semiconducting, conducting or insulating are patterned to form components of the integrated circuits. By way of example, the various materials are doped, ion implanted, deposited, etched, grown, etc., using various processes.

Photolithography is commonly utilized during integrated circuit fabrication. Photolithography comprises patterning of photoresist by exposing the photoresist to a pattern of actinic energy, and subsequently developing the photoresist. The patterned photoresist may then be used as a mask, and a pattern may be transferred from the photolithographically-patterned photoresist to underlying materials.

A continuing goal in semiconductor processing is to reduce the size of individual electronic components, and to thereby enable smaller and denser integrated circuitry. A concept commonly referred to as “pitch” can be used to quantify the density of an integrated circuit pattern. Pitch may be defined as the distance between an identical point in two neighboring features of a repeating pattern. However, due to factors such as optics and actinic radiation wavelength, a photolithographic technique will tend to have a minimum pitch below which the particular photolithographic technique cannot reliably form features. Thus, minimum pitches associated with photolithographic techniques present obstacles to continued feature size reduction in integrated circuit fabrication.

Pitch multiplication, such as pitch doubling, is one proposed method for extending the capabilities of photolithographic techniques beyond their minimum pitch. Such may involve forming features narrower than minimum photolithographic resolution by depositing layers to have a lateral thickness which is less than that of the minimum capable photolithographic feature size. The layers may be anisotropically etched to form sub-lithographic features. The sub-lithographic features may then be used for integrated circuit fabrication to create higher density circuit patterns than can be achieved with conventional photolithographic processing.

It is desired to develop new methodologies for pitch multiplication, and to develop processes for applying such methodologies to integrated circuit fabrication.

### BRIEF DESCRIPTION OF THE DRAWINGS

FIGS. 1-10 are diagrammatic cross-sectional views of a portion of a semiconductor construction at various steps of an example embodiment method.

FIGS. 11 and 12 are diagrammatic cross-sectional views of a portion of a semiconductor construction at sequential steps of an example embodiment method.

FIG. 13 is a simplified block diagram of a memory system in accordance with an embodiment.

FIG. 14 is a schematic diagram of a nonvolatile memory array in accordance with an embodiment.

### DETAILED DESCRIPTION OF THE ILLUSTRATED EMBODIMENTS

Some embodiments include methods in which a mass is formed over one or more materials that are to be patterned into a densely packed array of structures. Photolithographically-patterned photoresist is provided over the mass, with the patterned photoresist being a mask having a plurality of features formed at a first pitch. The patterned photoresist is utilized as a starting template for aligning spacers along sidewalls of the features, and such spacers are then used for forming a masking pattern in the mass. Some embodiments may utilize the patterned photoresist template to generate a high density masking pattern in the mass, with the high density masking pattern having a pitch that is reduced by about a factor of four relative to the pitch of the patterned photoresist template.

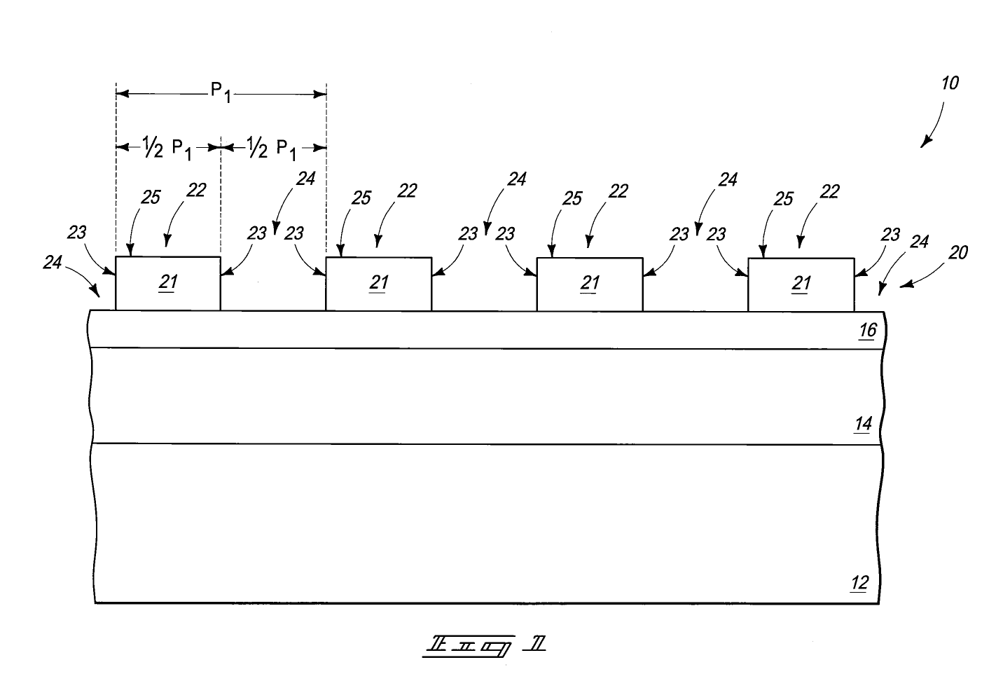

Example embodiments of methods of forming a pattern on a substrate are initially described with reference to FIGS. 1-10.

Referring to FIG. 1, such shows a construction 10 that comprises a base 12, a mass 14 over the base, a hardmask 16 over the mass, and a patterned mask 20 over the hardmask.

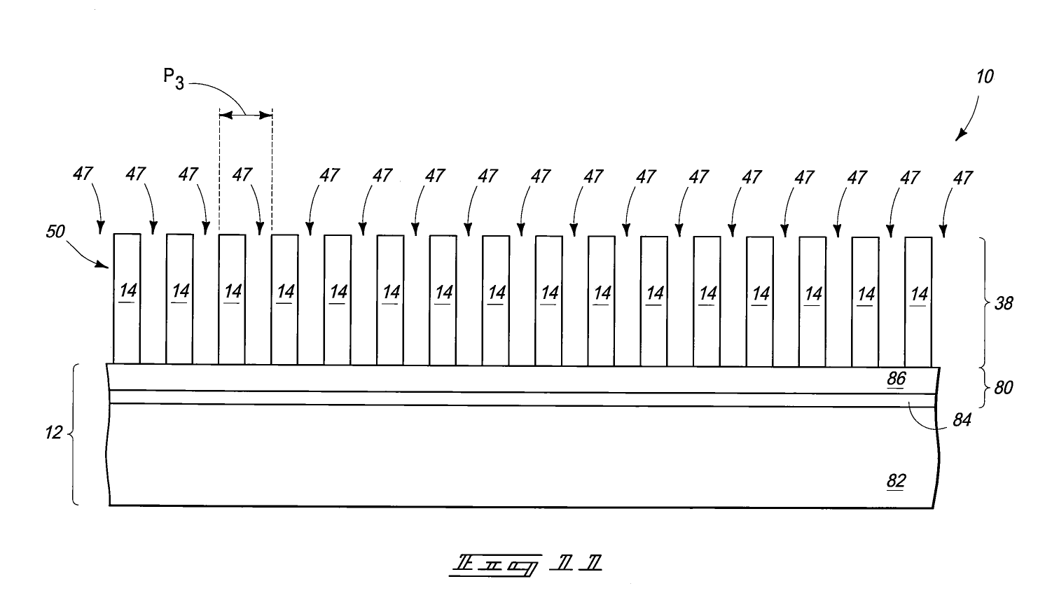

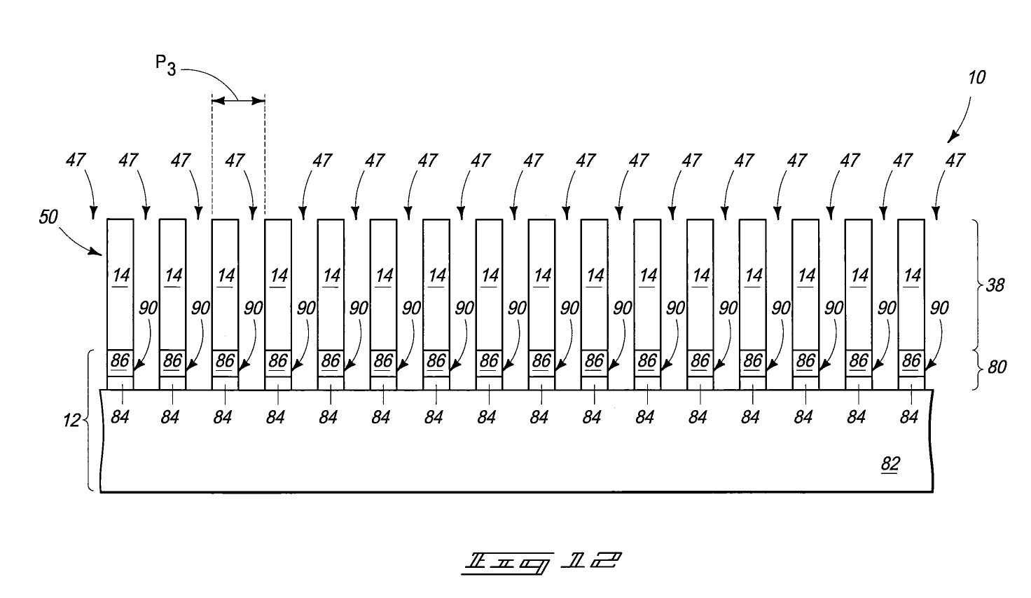

Base 12 comprises one or more materials which ultimately are to be patterned. The base is shown to be homogeneous in FIG. 1 in order to simplify the drawing. In some embodiments, the base may be homogeneous, as shown in FIGS. 1-10. In other embodiments, the base may be heterogeneous, with an example of such other embodiments being shown and described with reference to FIGS. 11 and 12. In some embodiments, the base may comprise semiconductor material (for instance, monocrystalline silicon of a silicon wafer), supporting one or more layers that are ultimately to be patterned into structures utilized in integrated circuitry. The various layers may comprise any suitable materials, such as, for example, one or more of various semiconductive materials, insulative materials, and conductive materials.

If base 12 comprises semiconductor material, the base may be referred to as a semiconductor substrate or semiconductor construction; with the terms “semiconductor substrate” and “semiconductor construction” meaning any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” means any supporting structure, including, but not limited to, the semiconductor substrates described above.

Mass 14 comprises a composition suitable for being selectively patterned with various spacers (described below), and suitable for being used to pattern one or more materials of the underlying base 12 (i.e., comprises a composition to which one or more materials of the underlying base may be selectively etched). In some embodiments, mass 14 may be entirely homogeneous, and in other embodiments mass 14 may be heterogeneous. In some embodiments, mass 14 comprises, consists essentially of, or consists of carbon. Example carbon-containing materials are amorphous carbon, transparent carbon, and carbon-containing polymers. Example carbon-containing polymers include spin-on-carbons (SOCs). An example thickness range for mass 14 is from about 700 Angstroms to about 2,000 Angstroms. In some embodiments, mass 14 may be sacrificial, and accordingly may be entirely removed after it has been utilized to pattern one or more materials of the underlying base.

Hardmask 16 may be homogeneous or heterogeneous. In some embodiments, hardmask 16 may correspond to a deposited antireflective coating (DARC), and may comprise, consist essentially of, or consist of silicon oxynitride. An example thickness range for hardmask 16 is from 200 Angstroms to 400 Angstroms. The hardmask 16 provides an etch stop between the patterned mask 20 and the mass 14. Such may be desired if the patterned mask 20 comprises a composition that is difficult to selectively remove relative to the mass 14 (for instance, if the patterned mask 20 and the mass 14 both comprise organic materials). The term “selective removal” means that one material is removed faster than another, which includes, but is not limited to, processes that are 100% selective for one material relative to another. In embodiments in which the patterned mask 20 comprises a composition that can be selectively removed relative to mass 14, the hardmask 16 may be omitted.

Patterned mask 20 comprises a material 21. Such material may, for example, comprise, consist essentially of, or consist of photoresist. If material 21 is photoresist, the material may be formed into the shown pattern with photolithographic processing (i.e., by exposing the photoresist to patterned actinic radiation, followed by utilization of developer to selectively remove some regions of the photoresist).

The patterned mask 20 comprises a plurality of spaced-apart features 22 (which may be referred to as first features), which alternate with gaps 24 between the features. In some embodiments, the features may correspond to lines extending in and out of the page relative to the shown cross-section of FIG. 1.

In the shown embodiment, the features 22 and gaps 24 are formed to a pitch, P₁, with individual features having widths ½P₁, and with individual gaps having widths ½P₁. In some embodiments, the widths ½P₁ may correspond to minimum photolithographic feature dimensions that may be formed with the photolithographic processing utilized to create patterned mask 20, and thus the pitch P₁ may correspond to a minimum pitch that can be created with such photolithographic processing.

Although the gaps and features are shown having the same widths as one another, in other embodiments at least some of the gaps may have widths different than at least some of the features. Also, in some embodiments one or more of the features may be formed to a different width than one or more of the other features; and/or one or more of the gaps may be formed to a different width than one or more of the other gaps.

In some embodiments, the shown region of construction 10 may correspond to a location where part of a memory array is to be formed, and the mask 20, together with subsequent processing described below, may be utilized to define a repeating pattern of structures that are ultimately to be formed across the memory array region.

Each of the features 22 comprises a pair of opposing sidewall surfaces 23, and a top surface 25 extending between the opposing sidewall surfaces.

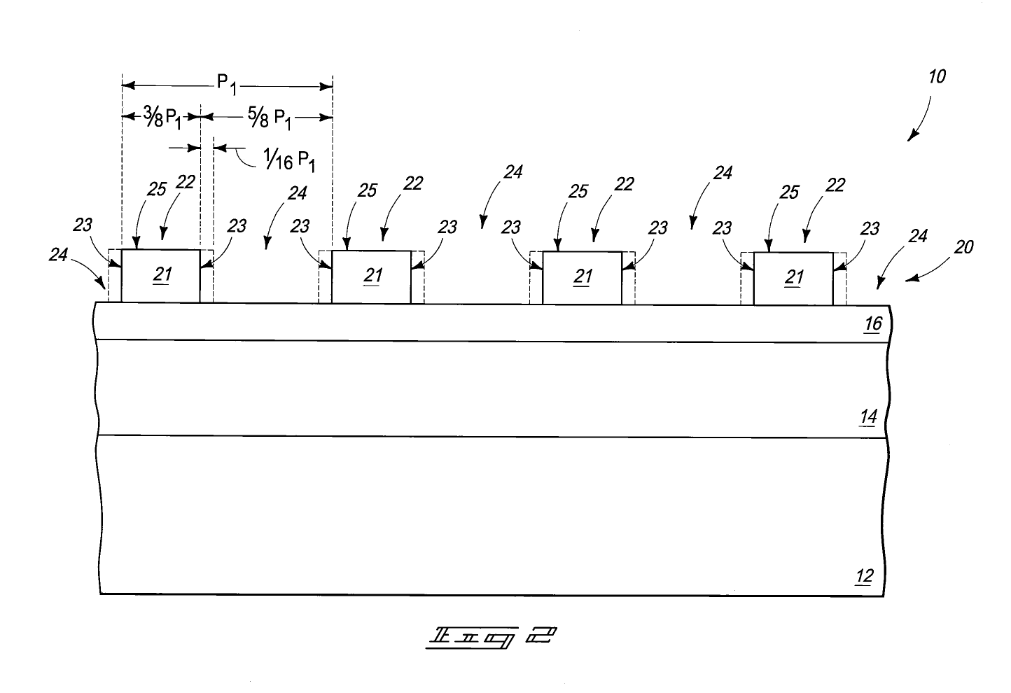

Referring to FIG. 2, the features 22 of the mask 20 have been laterally trimmed to remove 1/16P₁ from each side of the individual features. Such trimming reduces the widths of features 22 from the dimension of about ½P₁ of FIG. 1 to a dimension of about ⅜P₁. Such lateral trimming also causes a corresponding change in the widths of gaps 24, and specifically increases the widths of the gaps from a dimension of about ½P₁ of FIG. 1 to a dimension of about ⅝P₁. The pitch across the construction of FIG. 2 remains P₁, and thus the pitch is unaltered by the lateral trimming.

The lateral trimming of features 22 moves sidewalls 23 inwardly. The original locations of sidewalls 23 (i.e., the locations of the sidewalls at the processing stage of FIG. 1) is shown in FIG. 2 in dashed-line view to assist the reader in understanding the dimensional changes that occurred to the features 22 through the lateral trimming. Although the tops 25 of the features 22 are shown to be unaffected by the lateral trimming, in some embodiments the lateral trimming conditions may decrease the heights of features 22 and/or may induce other changes to the features (e.g., may impose a dome-shape to the features). For instance, lateral trimming conditions may be chosen which isotropically etch features 22.

The lateral trimming of features 22 may be omitted in some embodiments. If the lateral trimming is utilized, such lateral trimming may be accomplished with any suitable processing. For example, the construction depicted in FIG. 2 may be derived by plasma etching the substrate of FIG. 1 within an inductively coupled reactor. Example etching parameters which will achieve essentially isotropic etching where material of features 22 is photoresist and/or other organic-comprising material are pressure from about 2 mTorr to about 50 mTorr, substrate temperature from about 0° C. to about 100° C., source power from about 150 watts to about 500 watts, and bias voltage at less than or equal to about 25 volts. An example etching gas is a combination of Cl₂ from about 20 standard cubic centimeters per minute (sccm) to about 100 sccm and O₂ from about 10 sccm to about 50 sccm. If features 22 comprise a photoresist, such plasma etching will isotropically etch mask features 22 at a rate from about 0.2 nanometers per second to about 3 nanometers per second. While such an example etch is essentially isotropic, there may be more lateral etching of the spaced mask features than vertical etching since each feature has two sides laterally exposed, and only a single top surface vertically exposed.

If even more lateral etching is desired in comparison to vertical etching, example parameter ranges in an inductively coupled reactor may include pressure from about 2 mTorr to about 20 mTorr, source power from about 150 watts to about 500 watts, bias voltage at less than or equal to about 25 volts, substrate temperature of from about 0° C. to about 110° C., Cl₂ and/or HBr flow from about 20 sccm to about 100 sccm, O₂ flow from about 5 sccm to about 20 sccm, and CF₄ flow from about 80 sccm to about 120 sccm.

It may be desired that the stated etching provide greater removal from the top of the spaced mask features than from the sides, for example to either achieve equal elevation and width reduction or more elevation than width reduction. The example parameters for achieving greater etch rate in the vertical direction as opposed to the lateral direction may include pressure from about 2 mTorr to about 20 mTorr, temperature from about 0° C. to about 100° C., source power from about 150 watts to about 300 watts, bias voltage at greater than or equal to about 200 volts, Cl₂ and/or HBr flow from about 200 sccm to about 100 sccm, and O₂ flow from about 10 sccm to about 20 sccm.

The patterned mask 20 of FIG. 2 may be referred to as first patterned mask to distinguish such patterned mask from other patterned masks (discussed below) that may be subsequently formed; and the pitch P₁ may be referred to as an initial pitch to distinguish such pitch from pitches of the other patterned masks. If the lateral etching of FIG. 2 is not conducted, then the patterned mask 20 of FIG. 1 may be referred to as the first patterned mask.

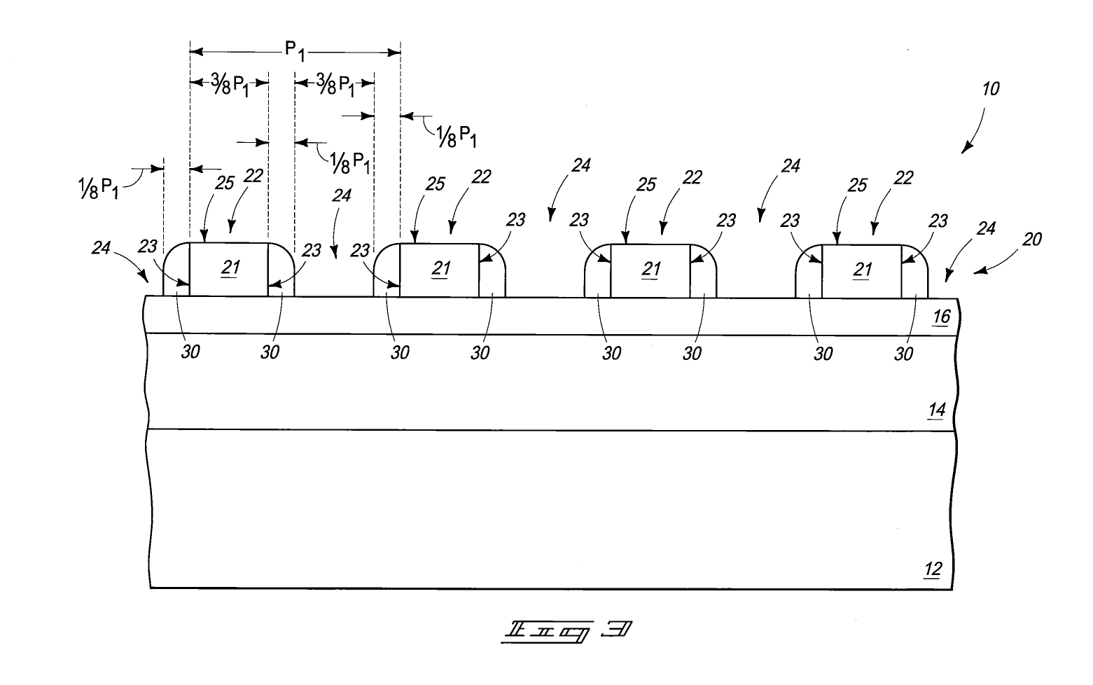

Referring to FIG. 3, spacers 30 are formed along the sidewall surfaces 23 of features 22. Spacers 30 are shown having widths of about ⅛P₁, and thus are shown reducing the widths of gaps 24 from the dimension of about ⅝P₁ of FIG. 2, to a dimension of about ⅜P₁.

Spacers 30 may comprise any suitable material (which may be referred to herein as spacer material), and may be formed with any suitable processing. In some embodiments, spacers 30 may comprise, consist essentially of, or consist of silicon dioxide. The silicon dioxide spacers may be formed by depositing a layer of silicon dioxide spacer material across an upper surface of construction 10 (utilizing chemical vapor deposition (CVD) or atomic layer deposition (ALD), for example); and then anisotropically etching such layer to leave the shown configuration of individual spacers 30. In some embodiments, the spacers may be formed by depositing a reactive (or alterable) material over the features 22, and then treating the material so that it forms spacers in the regions where the material is in suitable proximity to features 22. Example alterable materials are a class of materials available from Clariant International, Ltd. as so-called “AZ R” materials, such as the materials designated as AZ R200™, AZ R500™ and AZ R600™. The “AZ R” materials contain organic compositions which cross-link upon exposure to acid released from chemically-amplified resist. More specifically, an AZ R material may be coated across photoresist, and subsequently the resist may be baked at a temperature of from about 100° C. to about 120° C. to diffuse acid from the resist into the AZ R material to form chemical cross-links within regions of the AZ R material proximate the resist. Portions of the AZ R material adjacent the resist are thus selectively hardened relative to other portions of AZ R material that are not sufficiently proximate the resist. The AZ R material may then be exposed to conditions which selectively remove the non-hardened portions relative to the hardened portions. Such removal may be accomplished utilizing, for example, 10% isopropyl alcohol in deionized water, or a solution marketed as “SOLUTION CTM” by Clariant International, Ltd. Processes utilizing the “AZ R” materials are sometimes considered examples of RELACS (Resolution Enhancement Lithography Assisted by Chemical Shrink) processes.

A challenge with the “AZ R” materials is that they can be similar enough in composition to photoresist that it may be difficult to selectively remove photoresist relative to hardened AZ R materials. Accordingly, if alterable materials are used to form the spacers, it may be desirable to use mixtures that contain AZ R type materials in combination with one or more components that enhance subsequent selectivity for removal of photoresist relative to spacers formed from the mixtures. Components which may be dispersed in the mixtures may include, for example, one or more of titanium, carbon, fluorine, bromine, silicon and germanium, metals (for instance, titanium, tungsten, platinum, etc.) and metal-containing compounds (for instance, metal nitride, metal silicide, etc.).

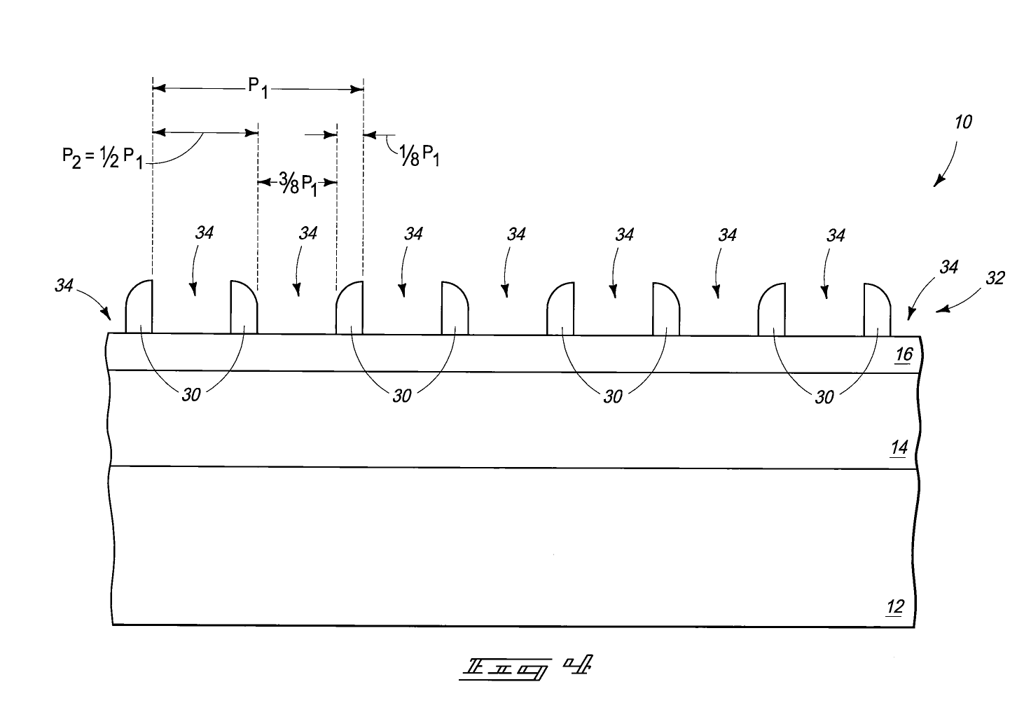

Referring to FIG. 4, features 22 (FIG. 3) of first patterned mask 20 (FIG. 3) are selectively removed relative to spacers 30 to leave a second patterned mask 32 corresponding to spacers 30.

The spacers 30 have widths of about ⅛P₁, and are spaced from one another by gaps 34 having widths of about ⅜P₁. Thus, the second patterned mask has a pitch, P₂, that is about ½P₁. The second patterned mask 32 may be considered to be self-aligned relative to the first patterned mask 20 (FIG. 3) due to the second patterned mask corresponding to spacers 30 that were aligned relative to sidewalls 23 (FIG. 3) of the features 22 (FIG. 3) of the first patterned mask. In some embodiments, spacers 30 may be considered to be second features that are aligned relative to the first features 22 (FIG. 3) of patterned mask 20 (FIG. 3).

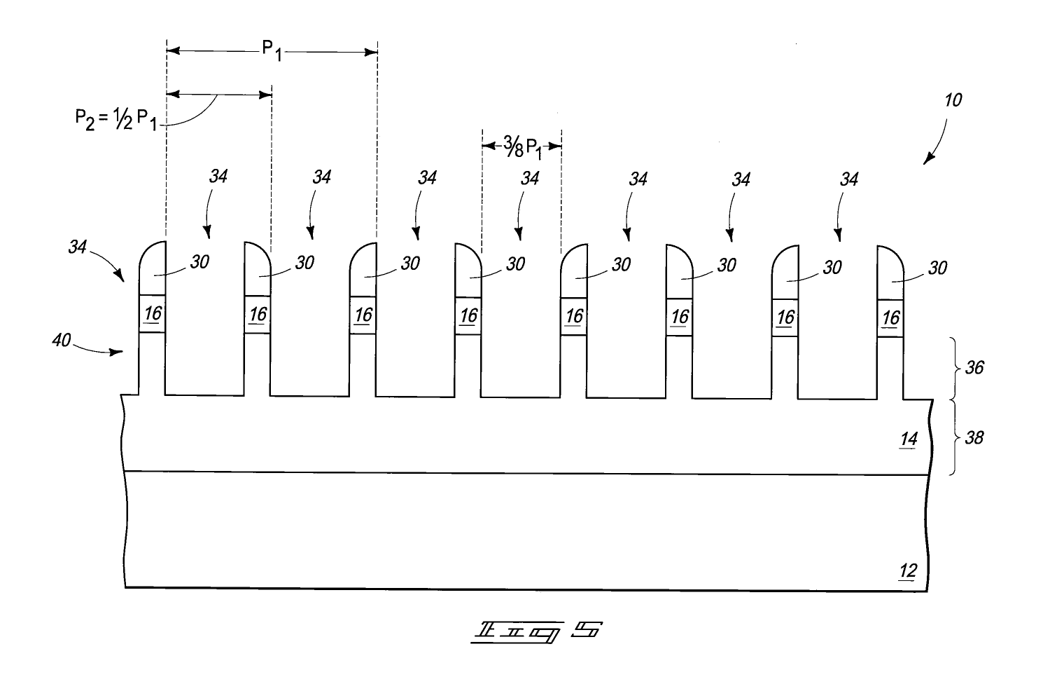

Referring to FIG. 5, a pattern of the second spacers is transferred through hardmask 16 and partially into mass 14. Such forms an upper portion 36 of mass 14 into a patterned mask, and leaves a lower portion 38 of mass 14 remaining unetched. The patterned upper portion of mass 14 may be considered to be a third patterned mask 40. Such third patterned mask has the same pitch, P₂, as the second patterned mask discussed above as corresponding to spacers 30.

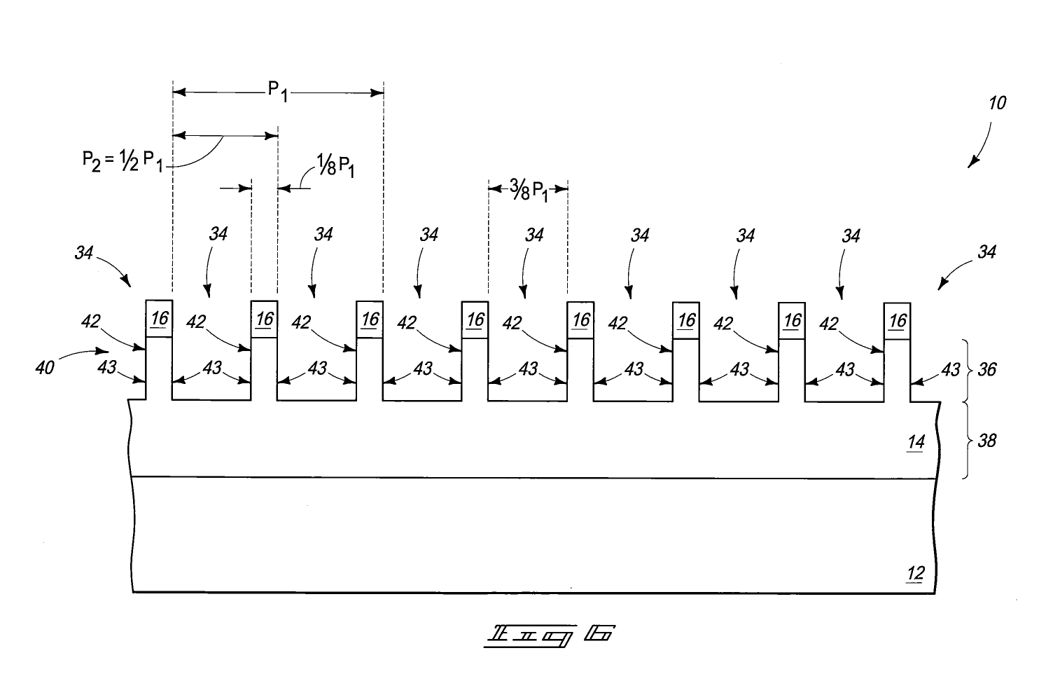

Referring to FIG. 6, spacers 30 (FIG. 5) are removed from over the third patterned mask 40. The third patterned mask comprises spaced-apart pedestals 42 of material 14, and in the shown embodiment such pedestals are capped with hardmask 16. The individual pedestals have widths of about ⅛P₁. The shown pedestals have substantially planar opposing vertical sidewall surfaces 43.

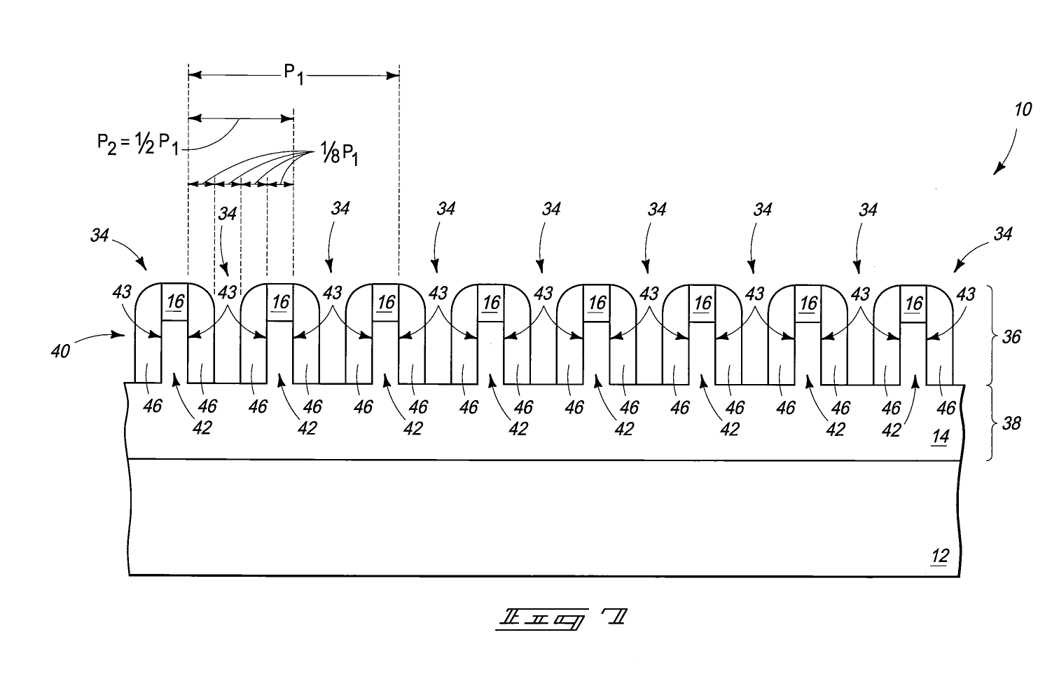

Referring to FIG. 7, spacers 46 are formed along the sidewall surfaces 43 of pedestals 42. Spacers 46 may be referred to as second spacers to distinguish them from the first spacers 30 described above with reference to FIGS. 3-5. Spacers 46 may be formed with any suitable method, including any of the methods described above as being suitable for formation of the first spacers. In some embodiments, the second spacers may comprise silicon dioxide; and may be formed by depositing a layer of silicon dioxide over an upper surface of construction 10, and then anisotropically etching such layer to leave the shown spacers 46.

In the shown embodiment, hardmask 16 remains over pedestals 42 as the spacers 46 are formed. In other embodiments, hardmask 16 may be removed from over pedestals 42 prior to forming spacers 46, and thus will not be present over pedestals 42 at the processing stage of FIG. 7.

The spacers 46 are shown having widths of about ⅛P₁, and thus are shown reducing the widths of gaps 34 from the dimension of about ⅜P₁ of FIG. 6 to a dimension of about ⅛P₁.

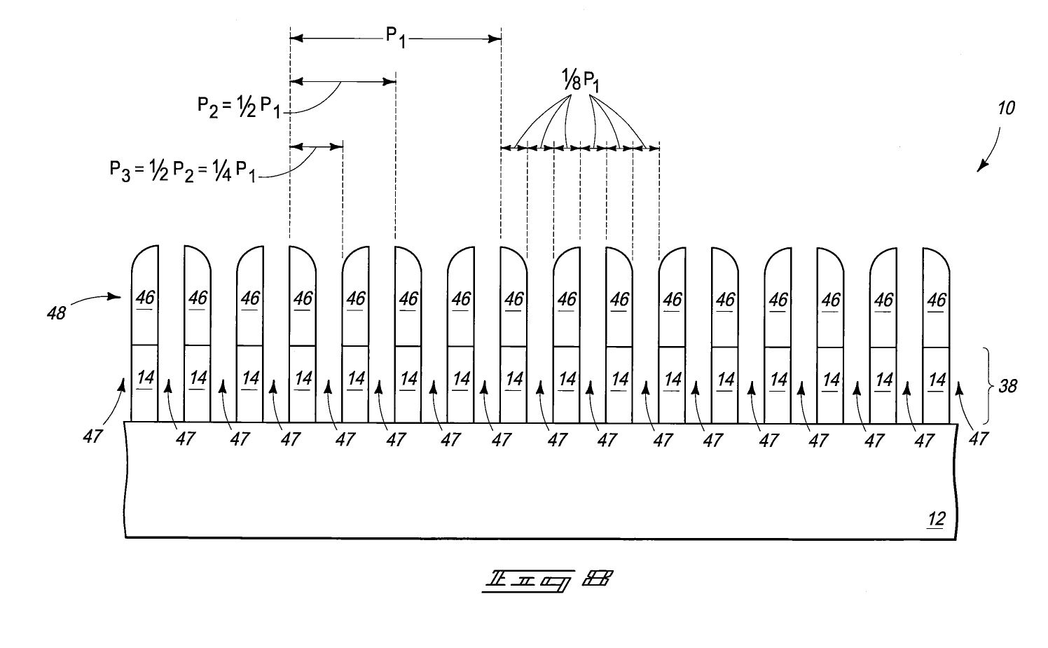

Referring to FIG. 8, mass 14 and material 16 (FIG. 7) are selectively removed relative to spacers 46 to form a plurality of gaps 47 that extend through the bottom portion 38 of mass 14. Some of the gaps 47 are in locations where gaps 34 (FIG. 7) are extended through the bottom portion 38 of mass 14. Others of the gaps 47 are in locations where the upper portion 36 (FIG. 7) of mass 14 is removed to form openings between the spacers 46, and where such openings are then extended through the bottom portion 38 of mass 14.

The spacers 46 may be considered to define a fourth patterned mask 48 that is utilized during an etch through the bottom portion 38 of mass 14. Such fourth patterned mask is aligned to the third patterned mask 40 (FIG. 6) corresponding to pedestals 42 (FIG. 6) since the fourth patterned mask was formed as spacers along sidewall edges of the pedestals 42.

The spacers 46 have widths of about ⅛P₁, and are spaced from one another by gaps 47 having widths of about ⅛P₁. Thus, the fourth patterned mask 48 has a pitch, P₃, that is about ¼P₁. The utilization of spacers 46 as a mask for patterning the bottom portion 38 of mass 14 has transferred a pattern into bottom portion 38, with such pattern having the pitch, P₃. Thus, the bottom portion 38 of the sacrificial mass 14 has a pattern formed therein to a pitch P₃ that is about ¼ of the original pitch P₁ of the patterned features 22 (FIG. 1). Accordingly, the processing of FIGS. 1-8 has created a final mask corresponding to the lower region 38 of mass 14, using a starting template corresponding to the mask 20 (FIG. 1), with such final mask having a substantially increased density of patterned features relative to the starting template. In the shown embodiment, the final mask has a pitch P₃ that is about ¼ of the pitch P₁ of the starting template, and thus the embodiment has a pitch multiplication factor of 4. In other embodiments, the pitch multiplication factor may be other than 4; and may or may not be an integer.

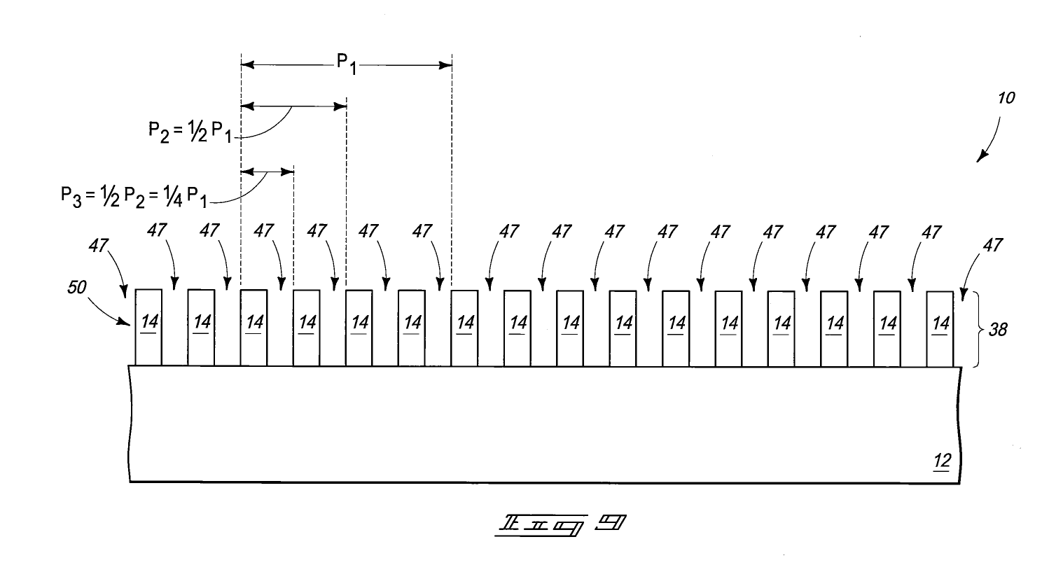

Referring to FIG. 9, spacers 46 (FIG. 8) are removed to leave a patterned mask 50 corresponding to the features formed in the bottom portion 38 of mass 14.

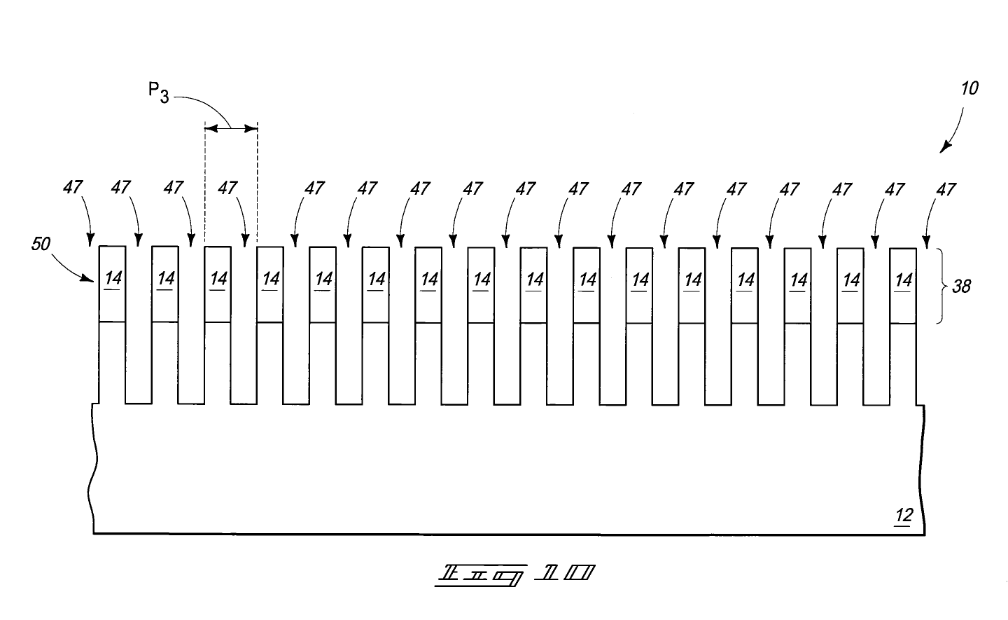

Referring to FIG. 10, the patterned mask 50 is utilized during etching of one or more materials of base 12, and thus openings 47 are shown extended into base 12. The etching of one or more materials of the base is one of several methods in which a pattern from mask 50 may be used to impart a pattern into one or more materials of base 12. Another example method comprises utilization of mask 50 to pattern a dopant implant.

Although spacers 46 (FIG. 8) are shown being removed prior to utilizing patterned mask 50 for imparting a pattern into base 12, in other embodiments the spacers 46 may remain at a processing stage analogous to that of FIG. 10 in which the patterned mask 50 is utilized for imparting a pattern into base 12.

The processing of FIGS. 1-10 may be utilized for patterning numerous devices, such as, for example, gates or other components utilized for nonvolatile memory devices (for instance, gates of NAND devices); and/or for patterning gates or other components of volatile memory devices. FIGS. 11 and 12 describe an example application in which gates of memory devices are patterned utilizing a mask of the type described in FIGS. 9 and 10.

Referring to FIG. 11, construction 10 is illustrated at a processing stage analogous to that described above with reference to FIG. 9, but in an embodiment in which base 12 comprises a gate stack 80 over a substrate 82.

Substrate 82 may, for example, comprise, consist essentially of, or consist of monocrystalline silicon.

Gate stack 80 comprises a semiconductor material 86 over a gate dielectric 84. The semiconductor material 86 may, for example, comprise polycrystalline silicon. In some applications, gate stack 80 may be utilized for forming field effect transistors, and in such applications material 86 may be a conductively-doped semiconductor material. Also, in such applications there may be an electrically insulative capping layer (not shown) provided over material 86 in the gate stack 80. The gate dielectric 84 may comprise any suitable material, and in some embodiments may comprise, consist essentially of, or consist of silicon dioxide.

In some applications, gate stack 80 may correspond to materials of a nonvolatile memory stack; and accordingly materials 84 and 86 may be tunnel dielectric material (for instance, silicon dioxide) and charge storage material (for instance, floating gate material, such as polysilicon), respectively.

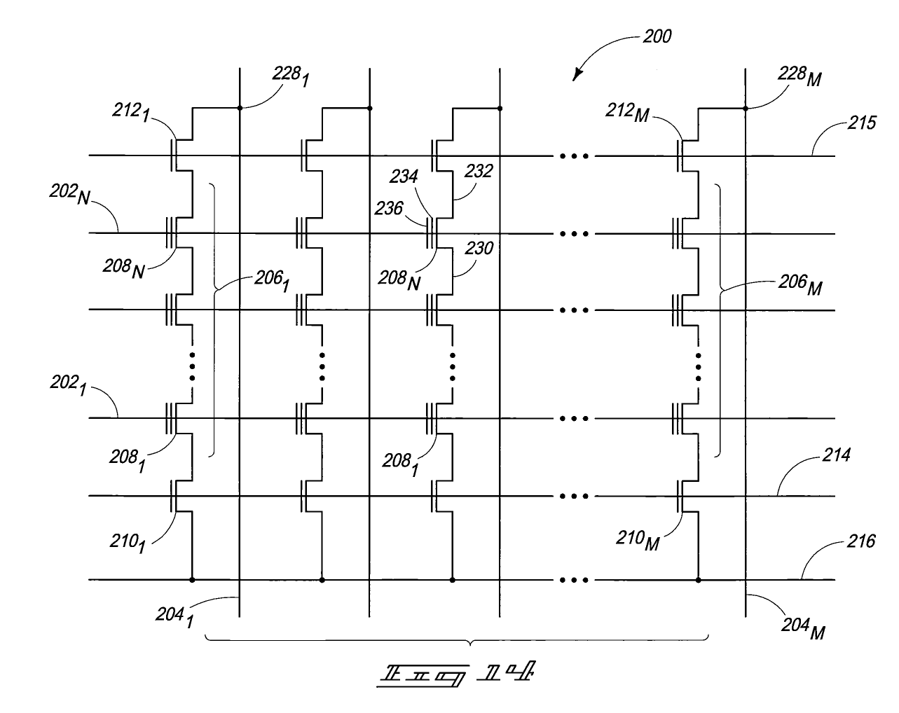

Referring to FIG. 12, openings 47 are extended through the materials of gate stack 80 with one or more appropriate etches to pattern the gate stack into a plurality of spaced structures 90. The structures 90 are formed at the pitch P₃ of the patterned mask 50. In embodiments in which gate stack 80 corresponds to a gate stack utilized to form field effect transistors, the structures 90 may correspond to wordlines extending in and out of the page relative to the cross-sectional view of FIG. 14; and subsequent processing may be utilized to form source/drain regions along such wordlines to create field effect transistors.

In subsequent processing (not shown), mask 50 may be removed from over the patterned gates 90.

If the patterned gate stack 80 of FIG. 12 comprises the tunnel dielectric and floating gate material, respectively, of a nonvolatile memory stack; subsequent processing (not shown) may be conducted to form dielectric material over the floating gate material, and to form control gate material over the dielectric material.

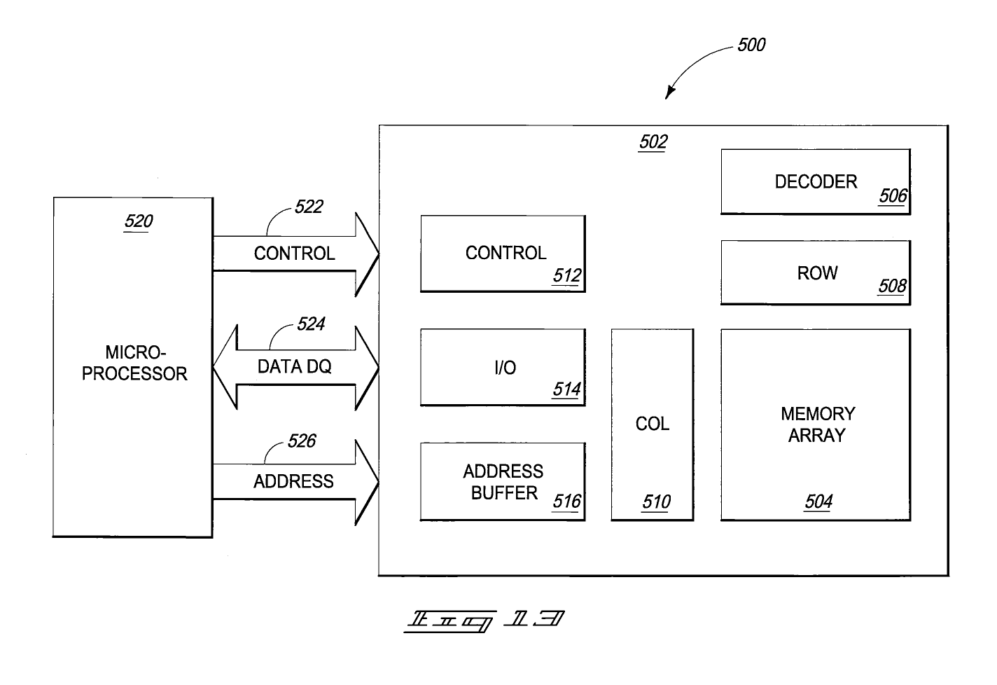

If the nonvolatile memory gates are patterned with processing of the type described with reference to FIGS. 1-12, such gates may be utilized in example configurations and applications of the types described in FIGS. 13 and 14.

FIG. 13 is a simplified block diagram of a memory system 500. The memory system includes an integrated circuit flash memory device 502 (e.g., a NAND memory device), that includes an array of memory cells 504, an address decoder 506, row access circuitry 508, column access circuitry 510, control circuitry 512, input/output (I/O) circuitry 514, and an address buffer 516. Memory system 500 also includes an external microprocessor 520, or other memory controller, electrically connected to memory device 502 for memory accessing as part of an electronic system. The memory device 502 receives control signals from the processor 520 over a control link 522. The memory cells are used to store data that is accessed via a data (DQ) link 524. Address signals are received via an address link 526, and are decoded at address decoder 506 to access the memory array 504. Address buffer circuit 516 latches the address signals. The memory cells may be accessed in response to the control signals and the address signals.

FIG. 14 is a schematic of an array 200 of memory cells. Such may be a portion of memory array 504 of FIG. 15, and may correspond to an array of NAND memory cells. Memory array 200 includes wordlines 202₁ to 202_{N}, and intersecting local bitlines 204₁ to 204_{M}. The number of wordlines 202 and the number of bitlines 204 may be each some power of two, for example, 256 wordlines and 4,096 bitlines. The local bitlines 204 may be coupled to global bitlines (not shown) in a many-to-one relationship.

Memory array 200 includes strings 206₁ to 206_{M}. Each string includes nonvolatile charge-storage transistors 208₁ to 208_{N}. The charge-storage transistors may use floating gate material to store charge, or may use charge-trapping material (such as, for example, metallic nanodots) to store charge.

The charge-storage transistors 208 are located at intersections of wordlines 202 and local bitlines 204. The charge-storage transistors 208 of each string 206 are connected in series source to drain between a source select gate 210 and a drain select gate 212. Each source select gate 210 is located at an intersection of a local bitline 204 and a source select line 214, while each drain select gate 212 is located at an intersection of a local bitline 204 and a drain select line 215.

A source of each source select gate 210 is connected to a common source line 216. The drain of each source select gate 210 is connected to the source of the first charge-storage transistor 208 of the corresponding string 206. For example, the drain of source select gate 210₁ is connected to the source of charge-storage transistor 208₁ of the corresponding string 206₁. The source select gates 210 are connected to source select line 214.

The drain of each drain select gate 212 is connected to a local bitline 204 for the corresponding string at a drain contact 228. For example, the drain of drain select gate 212₁ is connected to the local bitline 204₁ for the corresponding string 206₁ at drain contact 228₁. The source of each drain select gate 212 is connected to the drain of the last charge-storage transistor 208 of the corresponding string 206. For example, the source of drain select gate 212₁ is connected to the drain of charge-storage transistor 208_{N} of the corresponding string 206₁.

Charge-storage transistors 208 include a source 230, a drain 232, a charge storage region 234, and a control gate 236. Charge-storage transistors 208 have their control gates 236 coupled to a wordline 202. A column of the charge-storage transistors 208 are those transistors within a string 206 (or strings) that are coupled to a given local bitline 204. A row of the charge-storage transistors 208 are those transistors commonly coupled to a given wordline 202.

The embodiments discussed above may be utilized in electronic systems, such as, for example, computers, cars, airplanes, clocks, cellular phones, etc.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method of patterning one or more materials, comprising:
forming a homogeneous mass over said one or more materials; wherein the homogeneous mass comprises carbon;
forming a first patterned mask over the homogeneous mass, the first patterned mask comprising a plurality of spaced-apart features, the spaced-apart features having sidewall surfaces;
forming first spacers along the sidewall surfaces of the spaced-apart features;
removing the spaced-apart features to leave a second patterned mask corresponding to the first spacers;
partially etching into the homogeneous mass to transfer a pattern of the second patterned mask partially through the homogeneous mass; the partially etched homogeneous mass being a third patterned mask; the third patterned mask comprising spaced-apart pedestals that have sidewall surfaces, the spaced-apart pedestals of the third patterned mask being supported by an unetched remaining portion of the homogeneous mass;
removing the first spacers from over the third patterned mask, and then forming second spacers along the sidewall surfaces of the spaced-apart pedestals; the second spacers forming a fourth patterned mask;
etching through the remaining portion of the homogeneous mass to transfer a pattern of the fourth patterned mask through the homogeneous mass and to thereby pattern the homogeneous mass and form features comprising homogenous mass material and overlying second spacer material;
removing the second spacer material; and
utilizing the patterned homogeneous mass to impart a pattern into said one or more materials.

2. (canceled)

3. The method of claim 1 further comprising removing the homogeneous mass after transferring the fourth patterned mask into said one or more materials.

4. The method of claim 1 wherein the fourth patterned mask has a pitch that is approximately one-fourth of a pitch of the first patterned mask.

5. The method of claim 1 wherein the first patterned mask comprises photoresist, and wherein the forming of the first patterned mask comprises:
photolithographically patterning first blocks of the photoresist;
laterally trimming the first blocks of the photoresist to form the spaced-apart features from the first blocks of the photoresist.

6. The method of claim 1 wherein the first patterned mask comprises photoresist, and wherein the first spacers are formed by deposition of spacer material or by deposition of reactive material that is subsequently converted to spacer material.

7. The method of claim 1 wherein the imparting of the pattern to said one or more materials comprises etching into said one or more materials.

8. The method of claim 1 wherein the first spacers comprise silicon dioxide.

9. The method of claim 8 wherein the second spacers comprise silicon dioxide.

10. The method of claim 9 wherein the one or materials are materials of a field effect transistor gate stack.

11. The method of claim 9 wherein the one or materials are materials of a nonvolatile memory gate stack.

12. A method of patterning one or more materials, comprising:
forming a carbon-containing mass over said one or more materials; wherein the carbon-containing mass is homogeneous;
forming a hard mask over the carbon-containing mass;
forming a patterned photoresist mask over the hard mask, the patterned photoresist mask comprising a plurality of spaced-apart features, the spaced-apart features having sidewall surfaces;
forming silicon dioxide spacers along the sidewall surfaces of the spaced-apart features;
removing the spaced-apart features to leave a second patterned mask corresponding to the silicon dioxide spacers;
etching through the hard mask and partially into the carbon-containing mass to transfer a pattern of the second patterned mask through the hard mask, into an upper portion of the carbon-containing mass, and not into a lower portion of the carbon-containing mass; the upper portion of the carbon-containing mass being a third patterned mask; the third patterned mask comprising spaced-apart pedestals that have sidewall surfaces, the spaced-apart pedestals of the third patterned mask being supported by the lower portion of the carbon-containing mass;
removing the silicon dioxide spacers from over the third patterned mask, and then forming second spacers along the sidewall surfaces of the spaced-apart pedestals; the second spacers forming a fourth patterned mask;
etching through the remaining portion of the carbon-containing mass to transfer a pattern of the fourth patterned mask through the carbon-containing mass and to thereby pattern the carbon-containing mass forming features comprising carbon-containing mass material and overlying second spacer material;
removing the second spacer material; and
utilizing the patterned carbon-containing mass to impart a pattern into said one or more materials.

13. The method of claim 12 wherein the hard mask consists of silicon oxynitride.

14-15. (canceled)

16. The method of claim 12 wherein the hard mask is removed before forming the second spacers.

17. The method of claim 12 wherein the hard mask remains during the formation of the second spacers.

18. The method of claim 12 wherein the forming the patterned photoresist mask comprises photolithographically patterning the spaced-apart features.

19. The method of claim 12 wherein the forming the patterned photoresist mask comprises:
photolithographically patterning first blocks of the photoresist;
laterally trimming the first blocks of the photoresist to form the spaced-apart features from the first blocks of the photoresist.

20. The method of claim 12 wherein the first patterned mask has a pitch, P, and wherein the silicon dioxide spacers have a width of about ⅛ P.

21. The method of claim 20 wherein the second spacers have a width of about ⅛ P.

22. The method of claim 12 wherein the fourth patterned mask has a pitch that is approximately one-fourth of a pitch of the first patterned mask.

23. A method of forming memory cells, comprising:
forming a homogeneous mass over a memory gate stack; wherein the homogeneous mass comprises carbon;
forming a first patterned mask over the homogeneous mass, the first patterned mask comprising a plurality of spaced-apart first features;
forming second features aligned to the first features, the second features being formed on opposing sidewall surfaces of the first features;
removing the first features to leave a second patterned mask corresponding to the second features;
transferring a pattern of the second patterned mask only partially into the homogeneous mass to form an upper portion of the homogeneous mass into a third patterned mask, while leaving a lower portion of the homogeneous mass unaltered; the third patterned masking comprising third features;
forming fourth features aligned to the third features of the third patterned mask, the fourth features being formed on opposing surfaces of the third patterned mask; the fourth features forming a fourth patterned mask;
transferring a pattern of the fourth patterned mask through the lower portion of the homogeneous mass to form pattern features comprising homogenous mass material and overlying silicon dioxide; and
after removing the silicon dioxide, transferring the pattern of the fourth patterned mask through the memory gate stack to pattern the memory gate stack into a plurality of memory cells.

24. The method of claim 23 wherein the memory gate stack comprises an electrically conductive material directly over tunnel dielectric.

25. (canceled)

26. The method of claim 23 wherein the first patterned mask comprises photoresist.

27. The method of claim 23 wherein the first patterned mask comprises photoresist, and wherein the forming of the first patterned mask comprises:
photolithographically patterning first blocks of the photoresist;
laterally trimming the first blocks of the photoresist to form the spaced-apart features from the first blocks of the photoresist.
